(19) United States
(12) Patent Application Publication
(10) Pub. No.: US 2026/0360840 A1
(43) Pub. Date: Nov. 12, 2026

(54) FIELD FACTORY FOR BATTERY ENERGY STORAGE SYSTEM PRE-ASSEMBLY

(71) Applicant: AES Clean Energy Services, LLC, Salt Lake City, UT (US)

(72) Inventors: Michael Simpson, Centennial, CO (US); Felipe Cantero, Arvada, CO (US); Travis Stowers, Westminster, CO (US)

(73) Assignee: AES Clean Energy Services, LLC, Salt Lake City, UT (US)

(21) Appl. No.: 19/668,134

(22) Filed: May 5, 2026

Related U.S. Application Data
(60) Provisional application No. 63/800,705, filed on May 6, 2025.

(51) Int. Cl. H01M 10/42; G01R 31/66; H01M 10/627; H01M 50/251; H02J 9/06

(52) U.S. Cl. CPC H01M 10/425; G01R 31/66; H01M 10/627; H01M 50/251; H02J 9/06; H01M 2010/4271; H01M 2010/4278; H01M 2220/10

(57) ABSTRACT

A method for using a field factory to configure a battery energy storage system (BESS). A BESS may be difficult to configure in the field, particularly where the field is located in extreme environments. A field factory proximate to the field may be used for pre-assembly. As one example, the field factory may be used to configure a BESS subsystem enclosure including a container and constituent parts resident within or attached to the container. Configuration of the BESS subsystem may include electrical and/or mechanical configuration, and testing of the configuration prior to transport to the energy storage site of the BESS. At the energy storage site in the field, the configured BESS subsystem may be installed onto the pad and connected to the external components that are separate from the BESS subsystem.

### CROSS-REFERENCE TO RELATED APPLICATION

This application claims priority to U.S. Provisional Application Ser. No. 63/800,705 filed May 6, 2025, the entire disclosure of which is hereby incorporated by reference herein.

### TECHNICAL FIELD

The present disclosure relates generally to construction of a battery energy storage system. Specifically, the present disclosure relates to performing a pre-assembly at a field factory proximate to an energy storage site.

### BACKGROUND

This section is intended to introduce various aspects of the art, which may be associated with embodiments of the present disclosure. This discussion is believed to assist in providing a framework to facilitate a better understanding of particular aspects of the present disclosure. Accordingly, it should be understood that this section should be read in this light, and not necessarily as admissions of prior art.

A battery energy storage system (BESS) may be used to store energy for later use. The BESS typically uses a plurality of batteries to store electrical energy. The BESS may be used in various ways. For example, the BESS may be used to store excess energy generated from renewable sources like solar energy or wind energy. The BESS may also be used to stabilize the electrical grid by providing backup power, balancing supply and demand, and mitigating fluctuations in renewable energy production.

For safety and security, the batteries and other components of the BESS are enclosed by a BESS enclosure (e.g., a container including the batteries and other components of the BESS). Because these BESS enclosures are exceedingly heavy, the BESS enclosures require special permits to ship, with the shipping cost for the BESS enclosure being high.

Thus, the logistics to ship the BESS enclosure to the BESS construction site is costly and requires special handling. In addition to this logistic difficulty, the BESS construction site is typically an outdoor site where the presence of dust, moisture, temperature variations may pose a contamination risk to the system. These environmental impacts may make assembly of BESS and construction of BESS at the energy storage site even more difficult.

### SUMMARY

In one or some embodiments, a method of installing a battery energy storage system (BESS) at an energy storage site is disclosed in which certain actions are performed at a field factory and certain actions are performed at the energy storage site. In particular, the method includes: at a field factory, any one, any combination, or all of the following is performed: receiving, at the field factory locationally separate from the energy storage site, the plurality of battery modules; configuring, at the field factory, one or more pre-assembled BESS subsystems by: placing the plurality of battery modules on a mechanical structure disposed within a container for the pre-assembled BESS subsystem and configured to support the plurality of battery modules; electrically connecting each of the plurality of battery modules to an electrical transmission system configured to transfer electrical energy; electrically testing one or more electrical connections of the plurality of battery modules to the electrical transmission system; and configuring one or more of a fire suppression system, an internal climate control system, communication electronics, a sensor system, BESS subsystem control electronics, or a BESS subsystem universal power supply. The one or more pre-assembled BESS subsystems are transported from the field factory to the energy storage site. At the energy storage site, any one, any combination, or all of the following is performed: constructing one or more foundations (e.g., pads, piles, grade beams, etc.) at the energy storage site on which to support the one or more pre-assembled BESS subsystems; installing the one or more pre-assembled BESS subsystems on the one or more foundations; electrically connecting the plurality of battery modules to at least one power conversion system (PCS) via the electrical transmission system; and electrically testing one or more electrical connections of the plurality of battery modules to the at least one PCS.

In one or some embodiments, a method of installing a battery energy storage system (BESS) comprising a plurality of battery modules at an energy storage site is disclosed. The method includes: at a field factory, any one, any combination, or all of the following is performed: receiving, at the field factory locationally separate from the energy storage site, the plurality of battery modules; configuring, at the field factory, one or more pre-assembled BESS subsystems by: electrically connecting the plurality of battery modules to at least one power conversion system (PCS); electrically testing one or more electrical connections of the plurality of battery modules to the at least one PCS; and configuring one or more of a fire suppression system, an internal climate control system, communication electronics, a sensor system, BESS subsystem control electronics, or a BESS subsystem universal power supply. The one or more pre-assembled BESS subsystems is transported from the field factory to the energy storage site. At the energy storage site, any one, any combination, or all of the following is performed: constructing one or more foundations at the energy storage site on which to support the one or more pre-assembled BESS subsystems; installing the one or more pre-assembled BESS subsystems to the one or more foundations; communicatively connecting the one or more preassembled BESS subsystems to BESS control electronics configured to control the one or more pre-assembled BESS subsystems; and communicatively testing one or more communicational connections of the one or more pre-assembled BESS subsystems to the BESS control electronics.

### BRIEF DESCRIPTION OF THE DRAWINGS

The present application is further described in the detailed description which follows, in reference to the noted plurality of drawings by way of non-limiting examples of exemplary implementations, in which like reference numerals represent similar parts throughout the several views of the drawings. In this regard, the appended drawings illustrate only exemplary implementations and are therefore not to be considered limiting of scope, for the disclosure may admit to other equally effective embodiments and applications.

FIG. 1 is a block diagram illustrating an example battery energy storage system (BESS) in accordance with some embodiments.

FIG. 2 is a first flow diagram illustrating one example process of using a field factory to construct a BESS.

FIG. 3 is a second flow diagram illustrating one example process of using a field factory to construct a BESS.

FIG. 4 is a third flow diagram illustrating one example process of using a field factory to construct a BESS.

FIG. 5 is a top view of an illustration of the field factory.

FIG. 6 is a diagram of an example computer system that may be utilized to implement the methods described herein.

### DETAILED DESCRIPTION

The methods, devices, systems, and other features discussed below may be embodied in a number of different forms. Not all of the depicted components may be required, however, and some implementations may include additional, different, or fewer components from those expressly described in this disclosure. Variations in the arrangement and type of the components may be made without departing from the spirit or scope of the claims as set forth herein. Further, variations in the processes described, including the addition, deletion, or rearranging and order of logical operations, may be made without departing from the spirit or scope of the claims as set forth herein.

It is to be understood that the present disclosure is not limited to particular devices or methods, which may, of course, vary. It is also to be understood that the terminology used herein is for the purpose of describing particular embodiments only, and is not intended to be limiting. As used herein, the singular forms “a,” “an,” and “the” include singular and plural referents unless the content clearly dictates otherwise. Furthermore, the words “can” and “may” are used throughout this application in a permissive sense (i.e., having the potential to, being able to), not in a mandatory sense (i.e., must). The term “include,” and derivations thereof, mean “including, but not limited to.” The term “coupled” means directly or indirectly connected. The word “exemplary” is used herein to mean “serving as an example, instance, or illustration.” Any aspect described herein as “exemplary” is not necessarily to be construed as preferred or advantageous over other aspects. The term “uniform” means substantially equal for each sub-element, within about ±10% variation.

As used herein, “obtaining” data generally refers to any method or combination of methods of acquiring, collecting, or accessing data, including, for example, directly measuring or sensing a physical property, receiving transmitted data, selecting data from a group of physical sensors, identifying data in a data record, and retrieving data from one or more data libraries.

As used herein, terms such as “continual” and “continuous” generally refer to processes which occur repeatedly over time independent of an external trigger to instigate subsequent repetitions. In some instances, continual processes may repeat in real time, having minimal periods of inactivity between repetitions. In some instances, periods of inactivity may be inherent in the continual process.

If there is any conflict in the usages of a word or term in this specification and one or more patent or other documents that may be incorporated herein by reference, the definitions that are consistent with this specification should be adopted for the purposes of understanding this disclosure.

A battery energy storage system (BESS) may include various components, for example, battery modules, and other electronic components for electrical and communication controls and connections. In the fully constructed and installed BESS, some or all of these components may be enclosed in a container (interchangeably termed a BESS container or BESS enclosure). For example, a plurality of battery modules are typically enclosed in a container at the final BESS installation site.

When components that are enclosed within the container at the final BESS installation site are typically pre-assembled and enclosed in the container at an assembly facility, the fully assembled BESS enclosure should be delivered to the final BESS installation site (e.g., the energy storage site). However, because each BESS enclosure is exceedingly heavy, transporting the fully assembled BESS enclosure needs specialized equipment. Further, because of the weight of the BESS enclosure, the vehicle transporting the BESS enclosure is not able to get over most bridges and several roads. Therefore, transporting the fully assembled BESS enclosure may require exceeding logistics cost.

To avoid these limitations, some components, which are within the BESS container, may be assembled at the final BESS installation site (e.g., the energy storage site). However, the final BESS installation site (e.g., BESS energy storage site) is usually an outside area. Therefore, it may be difficult to assemble the BESS components in such an exposed uncontrolled environment. Further, the harsh conditions at the final BESS installation site may damage or deteriorate the components within the BESS enclosure. For example, to assemble and/or place the components within the container for the BESS enclosure at the final BESS installation site, the container door will be open at the final BESS installation site. The components for installation within the container and other previously installed components within the container may be exposed to dust, wind, humidity, and/or other environmental conditions.

Further, the energy storage site may include multiple BESS enclosures such that equipment to assemble or place the components of a respective BESS into a respective BESS enclosure may require movement to or configuration therein This movement might be across hundreds of acres and may occur significant cost.

In this regard, in one or some embodiments, a method configuring an energy storage site is disclosed that is less expensive. Alternatively, or in addition, a method is disclosed for efficient BESS construction.

The BESS may include one or more BESS subsystems. The BESS subsystem may include any one, any combination, or all of: a container, a plurality of battery modules, a mechanical structure, communication electronics, power electronics, control electronics, a universal power supply (UPS), sensors, a climate control system, and a fire suppression system. The BESS subsystem may further include one or more additional components.

The method for energy site configuration, such as BESS site configuration, uses a field factory (e.g., a pop-up factory) where at least a part of the configuration, such as the equipment that is necessary to assemble, install, and place components for the energy site configuration, is staged. For example, the field factory may have different pieces of equipment and/or different electrical equipment for pre-assembly of the BESS site configuration. After pre-assembly of at least a part of the BESS subsystem (e.g., the pre-assembled BESS subsystem), the pre-assembled BESS subsystem may be delivered to the energy storage site. Using the field factory may thus allow climate control and keep the dust, the wind, and/or the rain out. Further, the field factory may provide an efficient work environment and may ease the restrictions on work hours. For example, if the energy storage site is in a desert area, working hours for human workers may be limited such as from 4 am in the morning to 10 am in the morning due to extreme heat at the energy storage site. Even if it is possible to work after 10 am, workers may need to break every hour to avoid dehydration. This work environment is inefficient and potentially harmful to the workers. According to the method of various embodiments of the present disclosure, it is possible to keep the workers more often in a conditioned space, thereby increasing the efficiency of the workflow for the energy site configuration.

In one or some embodiments, a location of the field factory for a particular site is static and non-changing (e.g., the single location for the field factory serves the entire site of BESS system at the site, even if the BESS system includes multiple BESS subsystems on different foundations). Alternatively, the location of the field factory for a particular site may be dynamic and movable. For example, the field factory may be configured in a first location in order for pre-assembly of a part of the BESS system (e.g., a first set of BESS subsystem(s)). After which, the field factory may be moved to a second location that is different from the first location in order for pre-assembly of another part of the BESS system (e.g., a second set of BESS subsystem(s)). In this way, the field factory may be moved one or more times (e.g., to different concrete foundations within the BESS system).

Regardless, in one or some embodiments, the field factory may pre-assemble (e.g., configure and/or test) the BESS subsystem, hereinafter referred to as a pre-assembled BESS subsystem. The pre-assembly of the BESS subsystem may comprise any one, any combination, or all of: mechanical pre-assembly (e.g., configuring the mechanical structure to support the batteries within a respective container and/or placing the batteries onto the mechanical support within the respective container); communication pre-assembly (e.g., configuring and/or testing communication electronics for communication within and/or external to the respective container); climate control pre-assembly (e.g., installation and/or testing of the climate control subsystem); fire suppression pre-assembly (installation of the fire suppression system; testing of the fire suppression system; and/or configuration of the fire suppression system (e.g., filling the fire suppression system containers with flame retardant or water); control electronics pre-assembly (installation and/or testing of internal control electronics); power electronics pre-assembly (installation and/or testing of the electrical transmission system and/or the PCS); power supply pre-assembly (e.g., installation and/or testing of the universal power system); or sensor pre-assembly.

As discussed in more detail below, the pre-assembled BESS subsystem may include separate, but similar, devices that are external to the pre-assembled BESS subsystem, including any one, any combination, or all of: the climate control system (e.g., an external climate control system that is external to the pre-assembled BESS subsystem versus an internal climate control system that is installed internally to the pre-assembled BESS subsystem); communication electronics (e.g., external communication electronics that is external to the pre-assembled BESS subsystem versus internal communication electronics that is installed internally to the pre-assembled BESS subsystem, with the external communication electronics and the internal communication electronics communicating with each other); power electronics (e.g., external PCSs that is/are external to the pre-assembled BESS subsystem versus internal PCSs that is/are installed internally to the pre-assembled BESS subsystem); control electronics (e.g., external control electronics that may be external to at least one of the pre-assembled BESS subsystem and configured to control a plurality of pre-assembled BESS subsystem versus internal control electronics that is installed internally to a respective pre-assembled BESS subsystem and configured to control the respective pre-assembled BESS subsystem, such as only to control the respective pre-assembled BESS subsystem); power supplies (e.g., an external universal power supply that is external to and powers electronics external to at least one pre-assembled BESS subsystem and an internal universal power supply that is internal to and powers electronics internal to the at least one pre-assembled BESS subsystem). Thus, as discussed in more detail below, the field factory may install and/or test devices, with those same devices being installed at the energy storage site.

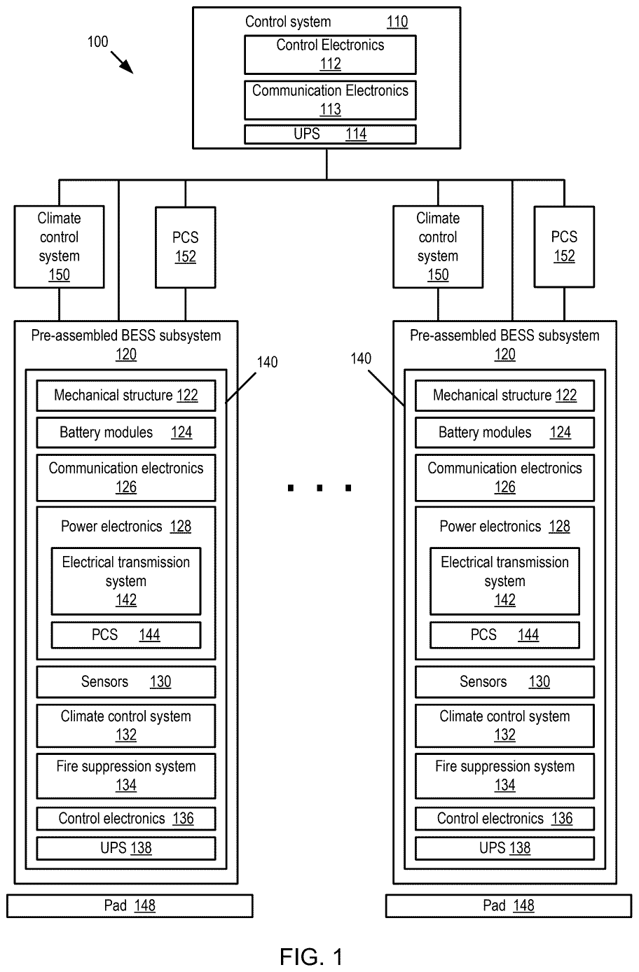

FIG. 1 is a block diagram illustrating an example BESS site configuration 100 in accordance with some embodiments. Referring to FIG. 1, the BESS site configuration 100 may include one or more pre-assembled BESS subsystems 120.

In some embodiments, the pre-assembled BESS subsystem 120 may be preassembled before being delivered to the energy storage site (e.g., the final BESS construction site for energy storage). In some embodiments, the pre-assembled BESS subsystem 120 may be pre-assembled in a controlled environment that is remote from the final site. For example, the pre-assembled BESS subsystem 120 may be pre-assembled in a field factory (interchangeably termed a pop-up factory or a pre-assembly factory) within a controlled environment, which may reduce the logistics cost for the construction of the BESS system ultimately installed at the energy storage site and which may provide better quality control. The field factory may be remote from the energy storage site but still be within a specific distance from the energy storage site.

In practice, the field factory may be constructed in close proximity to the energy storage site under construction. In one embodiment, close proximity comprises within driving distance of the energy storage site (e.g., at least 1 mile; less than 1 mile; less than 2 miles; less than 3 miles; less than 4 miles; less than 5 miles; less than 10 miles; less than 20 miles; no greater than 1 mile; no greater than 5 miles; no greater than 10 miles; no greater than 20 miles; etc.). Alternatively, close proximity comprises within a crane (such as a static crane or mobile crane) operating distance (e.g., less than 100 feet; less than 200 feet; less than 300 feet; less than 400 feet; less than 500 feet; less than 1,000 feet; less than 2,000 feet; less than 3,000 feet; less than 4,000 feet; less than 1 mile; etc.).

The pre-assembled BESS subsystem 120 may include a container and preassembled BESS subsystem components including any one, any combination, or all of: a mechanical structure 122; a plurality of battery modules 124; communication electronics 126 (e.g., BESS subsystem communication electronics); power electronics 128 (e.g., BESS subsystem power electronics); sensors 130 (e.g., BESS subsystem sensors); a climate control system 132 (e.g., BESS subsystem climate control system); a fire suppression system 134 (e.g., BESS subsystem fire suppression system); control electronics 136 (e.g., BESS subsystem control electronics); or a UPS 138 (e.g., BESS subsystem UPS). In this regard, in one or some embodiments, separate from placing the batteries within or on a mechanical structure of the container, electrically connecting and testing the electrical connection, the field factory may configure any one, any combination, or all of: the fire suppression system 134; the climate control system 132; communications electronics 126; a sensor system (e.g., sensor(s) 130); control electronics 136; or a universal power supply system (e.g., UPS 138).

Thus, in some embodiments, the pre-assembled BESS subsystem components may be enclosed in or at least disposed on the container 140. For example, any one, any combination, or all of the mechanical structure 122, the plurality of battery modules 124, communication electronics 126, power electronics 128, sensors 130, the climate control system 132, the fire suppression system 134, control electronics 136, or the UPS 138 may be enclosed in, disposed on, or attached to the container 140, with such enclosure therein, disposition thereon, or attachment thereto being performed at the field factory, as discussed in more detail below. For example, the mechanical structure 122 and the plurality of battery modules 124 supported by the mechanical structure 122 may be enclosed in the container 140. In addition to the mechanical structure 122 and the plurality of battery modules 124, any one, any combination, all of the following may be enclosed within the container 140: communications electronics 126; power electronics 128; sensor(s) 130; climate control system 132; a fire suppression system 134; control electronics 136; or UPS 138.

The container 140 may comprise a mechanical structure with strength suitable to withstand shipment, storage, and handling. In one or some embodiments, the container 140 may be custom designed for storing a plurality of battery modules 124. In some embodiments, the container 140 may be compatible with the shipping standards, such as specific mounting points in specific locations in order for the container 140 to be stacked on top of another shipping container. In one or some embodiments, the container 140 may have a length greater than a width. The container 140 may have one or more doors for access inside of the container, with the one or more doors being formed at a wider side of the container 140. In one or some embodiments, the doors may be formed along the entire length of the wider side. However, the type and shape of the container 140 is not limited thereto and other types of containers that are suitable to withstand shipment and store a plurality of battery modules 124 and other components of the pre-assembled BESS subsystem may be used.

The plurality of battery modules 124 are configured to provide or store electrical energy. Each of the plurality of battery modules 124 may include battery cells where energy may be stored and released. The battery modules 124 may use one or more types of battery chemistries, including lithium-ion, lead-acid, or sodium-sulfur, and the like. The battery cells included in the battery module 124 are not limited, and future developed battery cells may also be used for the battery module 124. The battery module 124 may further include a battery management system (BMS) to ensure the safe and efficient operation of the battery cells. The BMS may monitor and/or manage state of charge and/or state of health. The BMS may further conduct cell balancing to unify charge levels across the battery cells. The BMS may also conduct temperature control that monitors and controls the temperature of the battery cells to avoid overheating of the battery cells. The battery module 124 may further include a cooling system to maintain a predetermined operating temperature for the battery cells and the overall modules. The cooling system may include an air-cooling system and/or a liquid cooling system. For example, the liquid cooling system for the battery module 124 may include pipes/tubes configured to carry a coolant through the battery module for heat exchange, and a pump to circulate the coolant through the pipes/tubes. The battery module 124 may further include other components to manage and control the battery cells and the battery module 124.

The mechanical structure 122 is configured to support the plurality of battery modules 124. The mechanical structure 122 may also support other components of the preassembled BESS subsystem, such as any one, any combination, or all of: communications electronics 126; power electronics 128; sensors 130; a climate control system 132; a fire suppression system 134; control electronics 136; or a UPS 138. The mechanical structure 122 may include a plurality of slots to store and support the plurality of battery modules 124. The mechanical structure 122 may further include spaces to store and support other components of the pre-assembled BESS subsystem, such as any one, any combination, or all of: communications electronics 126; power electronics 128; sensors 130; a climate control system 132; a fire suppression system 134; control electronics 136; or a UPS 138. The mechanical structure 122 may include any one, any combination, or all of: a cabinet; a rack; or a similar structure.

The communication electronics 126 may include any one, any combination, or all of: receiver(s); transmitter(s); transceiver(s); communication wires for communication between the different elements; wireless receiver(s); wireless transmitter(s); wireless transceiver(s); or router(s).

The power electronics 128 may include one or both of an electrical transmission system 142 or a power conversion system (PCS) 144. As shown in FIG. 1, The electrical transmission system 142 may include a power bus. The power bus may include one or both of an AC bus or DC bus. The electrical transmission system 142 may also include conductive cables/wires configured to transfer electrical energy therethrough. The PCS 144 may comprise one or more inverters and may be configured to perform one or more functions, such as any one, any combination, or all of: electrical power conversion from DC power to AC power and/or vice versa (e.g., by using one or more inverters); maintain continuous operation of a load (e.g., provide constant power to the load); supply power to load(s) (e.g., for a local microgrid or to the utility grid); or perform one or more safety functions (e.g., use one or more safety mechanisms, such as contactors, breakers, fuses or the like). Thus, one function of the PCS is for power conversion (e.g., PCS may perform power conversion, such as one or both of DC to AC conversion or vice versa). In this regard, any discussion herein regarding the PCS may be generally applied to power conversion, such as one or both of DC to AC conversion or vice versa. For example, an inverter may be used to perform power conversion (e.g., either DC to AC conversion or vice versa). As such, any discussion herein regarding the PCS may generally be applied to an inverter. In some embodiments, an additional power source (e.g., a universal power supply (UPS)), separate from the battery modules 124 may be used. In such an instance, the power electronics 128 may include wires to transmit the power from the additional power source to the electronic components.

In one or some embodiments, the pre-assembled BESS subsystem 120 includes the PCS 144 enclosed within the container 140. In other embodiments, the pre-assembled BESS subsystem 120 does not include the PCS 144 within the container 140; rather, the PCS 152 may be placed the outside the container 140 as a separate component from the pre-assembled BESS subsystem 120. In this example, the PCS 152 may be located near the pre-assembled BESS subsystem 120 at the energy storage site and be electrically connected to the preassembled BESS subsystem 120 at the energy storage site. In some embodiments, the BESS site configuration 100 may include a PCS 144 located within the container 140 (e.g., included in the pre-assembled BESS subsystem) and/or a PCS 152 located outside the container 140 as a separate component from the pre-assembled BESS subsystem 120.

The sensors 130 may be configured to monitor one or more aspects, such as the condition, of pre-assembled BESS subsystem 120 and may be used to optimize the BESS performance, safety, and efficiency. The sensors 130 may include any one, any combination, or all of: a temperature sensor; a humidity sensor; or a fire detection sensor. The temperature sensor may monitor the temperature of the battery modules 124 and surrounding environment, for example, the temperature of the inside of the container 140 enclosing the battery modules 124 and other components. The humidity sensor may measure the moisture level around the battery modules 124 or moisture level of the inside of the container 140. The fire detection sensor may include a smoke detector, which may use optical or ionization methods to detects smoke particles in the air, a heat sensor, which may monitor temperature change and trigger alarms when a specific temperature threshold is exceeded, or a gas sensor, which may detect emission of specific gas.

The climate control system 132 may include any one, any combination, or all of: a heater; a cooler; a humidity controller; or a ventilation unit. The heater, cooler, humidity controller, and a ventilation unit may be combined into a single device such as a HVAC (Heating, Ventilation, and Air Conditioning) unit. The climate control system 132 may also include a fan to cool the electronic device. Some or all parts of the climate control system 132 may be within the container 140 or outside the container 140. In some embodiments, the entire climate control system 132 may be disposed on or enclosed in the container 140. In other embodiments, some part of the climate control system 132 (e.g., a fan) may be disposed on or enclosed in the container 140 and other parts of the climate control system (e.g., climate controller, air blower, and the like) may be positioned outside the container 140 as a separate component from the pre-assembled BESS subsystem 120. This is illustrated in FIG. 1 as element 150. Thus, in one or some embodiments, part(s) of the climate control system may be external to the container 140 (and illustrated as element 150). Such part(s) of the climate control system may be installed at the energy storage site. Alternatively, or in addition, the entire climate control system (shown as element 150) may be external to the container 140 and installed at the energy storage site. Regardless, any discussion herein regarding the climate control system may comprise part or all of the climate control system.

The fire suppression system 134 include any one, any combination, or all of: a fire extinguisher; a sprinkler system; a water mist system; a foam suppression system; or a clean-agent system (e.g., non-conductive gases or chemicals that extinguish fires without leaving residue). In some embodiments, the fire suppression system 134 may include a tank configured to hold extinguishing agent, valve assembly configured to control the release of the extinguishing agent, and a hose configured to distribute the extinguishing agent.

In some embodiments, some or all of the sensors 130 may be incorporated into the climate control system 132 and/or the fire suppression system 134. Various types of sensors 130 are contemplated, including any one, any combination, or all of: electrical sensors; temperature sensors; smoke sensors; etc.

In some embodiments, the BESS site configuration 100 may also include a control system 110. The control system 110 may control any one, any combination, or all of components of the BESS site configuration 100, such as devices external to the pre-assembled BESS subsystem 120 (e.g., the climate control system 150 external to the pre-assembled BESS subsystem 120; the PCS 144) and/or devices internal to the pre-assembled BESS subsystem 120 (e.g., communication electronics 126; PCS 144; sensors 130; climate control system 132; fire suppression system 134; control electronics 136; or UPS 138). In one or some embodiments, control system 110, using communication electronics 113, may communicate directly with devices internal to the pre-assembled BESS subsystem 120. Alternatively, or in addition, control system 110 may communicate indirectly with devices internal to the preassembled BESS subsystem 120 (e.g., communicating with control electronics 136, which in turn routes communications to/from the devices internal to the pre-assembled BESS subsystem 120).

In some embodiments, the control system 110 may be separate from the preassembled BESS subsystem 120 and may be connected to the pre-assembled BESS subsystem 120 at the energy storage site. The control system 110 may include control electronics 112, communication electronics 113, and the UPS 114. In some embodiments, the control electronics 112 include hardware (e.g., computer architecture and software programmed therein), which when executed, is configured to control the various parts of the BESS site configuration 100, as discussed herein. In one or some embodiments, the control system 110 may communicate (e.g., wired and/or wirelessly) with the one or more pre-assembled BESS subsystem 120. For example, the control electronics 112 may communicate, using communication electronics 113 (e.g., wired and/or wirelessly), with each component of the pre-assembled BESS subsystem 120, thereby controlling various parts of the BESS site configuration 100 according to commands from the control electronics 112. In one particular example, the control electronics 112 may communicate with any one, any combination, or all of: the battery modules 124; communication electronics 126; the power electronics 128 (e.g., PCS 144); the sensors 130; the climate control system 132; or the fire suppression system 134. The UPS 138 may supply power to one or more electronic devices, such as control electronics 136, the power electronics 128 (e.g., PCS), and/or other components of the pre-assembled BESS subsystem 120. Typically, the UPS 138 is configured to supply power to the one or more electronic devices on a short-term basis until power may be supplied from the battery modules 124.

Additionally, or alternatively, the pre-assembled BESS subsystem 120 may include the control electronics 136, which may be enclosed within the container 140 for the preassembled BESS subsystem 120. In some embodiments, the control electronics 112 may solely belong to or be associated with control system 110 and may be separate from the control electronics 136 in the pre-assembled BESS subsystem 120. In some embodiments, the control electronics may be located both within (see control electronics 136) and outside (see control electronics 112) the container 140 for the pre-assembled BESS subsystem 120. In other words, BESS site configuration 100 may include the control electronics as separate components, so that part of the control electronics (see control electronics 136) may be included in the preassembled BESS subsystem 120 (e.g., assembled and/or tested at the field factory) and another part of the control electronics (see control electronics 112) may be assembled and/or tested at the energy storage site and may be separate from the pre-assembled BESS subsystem 120 (e.g., the control electronics 112 included in the control system 110 that is separate from the control electronics 136 in the pre-assembled BESS subsystem 120).

In one or some embodiments, the pre-assembled BESS subsystem 120 may include the UPS 138, which may be enclosed within the container 140 for the pre-assembled BESS subsystem 120. In some embodiments, the UPS may only provide power to control system 110 separate from the pre-assembled BESS subsystem 120. See UPS 114. In some embodiments, the UPS may be located both within and outside the container 140 for the pre-assembled BESS subsystem 120. See UPS 138. In this regard, BESS site configuration 100 may include one or more UPSs, such as UPS 114 and/or UPS 138. Further, the UPS may comprise multiple parts, with at least one part included in the pre-assembled BESS subsystem 120 at the field factory, and at least another part of the UPS 114 separate from the pre-assembled BESS subsystem 120 being assembled at the energy storage site (e.g., the UPS 114 included in the control system 110 that is separate from the UPS 138 that is in the pre-assembled BESS subsystem 120).

Referring back to FIG. 1, the BESS site configuration 100 may further include one or more pads 148, each of which may mechanically and/or electrically support the preassembled BESS subsystem 120 at the energy storage site. As discussed above, different types of foundations are contemplated, including pads, piles, or grade beams. In this regard, any discussion regarding pads may be applicable to any type of foundation.

Thus, at the energy storage site, the pre-assembled BESS subsystem 120 may be physically placed onto the pad 148. The pad 148 may be a flat slab of concrete and may include re-bar and/or metal stakes. Portions of the re-bar and/or the metal stakes may be embedded in the pad 148 and driven into earth ground. Also, at least a portion (e.g., an upper end portion) of the re-bar and/or the metal stakes may be exposed from the pad 148. For example, the upper end portion of the re-bar and/or the metal stake may protrude from the pad 148. At the energy storage site, the exposed portion of the re-bar or the metal stake may be electrically connected to the chassis of the container 140 for the pre-assembled BESS subsystem 120 when the preassembled BESS subsystem is placed on the pad 148 at the final energy storage site. The thickness of the pad 148 may vary depending on the location of the energy storage site and/or the condition of the ground. For example, the thickness of the pad 148 may be 6 inches or 12 inches.

In some embodiments, pre-assembly (e.g., pre-configuration) of the pre-assembled BESS subsystem 120 at the field factory may include one or both of electrical pre-configuration at the field factory or mechanical pre-configuration at the field factory, and then the preassembled BESS subsystem 120 may be delivered to and installed at the final energy storage site.

In one or some embodiments, electrical pre-configuration at the field factory may comprise any one, any combination, or all of the following: pre-wiring for purposes of power (energy) transfer; pre-wiring and/or pre-configuration for communication (e.g., wired and/or wireless) between the different elements within the container 140 or external to the container 140 (e.g., in one instance, pre-wiring for communication between the different elements; in another instance, pre-configuring for wireless communication with wireless receivers/transmitters so that, upon powering the wireless receivers/transmitters at the deployment site, communication may be performed without additional configuration); or pre-wiring for purposes of grounding. Alternatively, or in addition, electrical pre-configuration may comprise one or more electrical devices within or on the container 140.

As one example, pre-wiring for purposes of power transfer may comprise pre-configuring the electrical transmission system 142, for example, one or both of an AC bus or DC bus that may be resident within the container 140. In one or some embodiments, the AC bus may be pre-wired for electrical connection to the AC output of the PCS 144 and to one or more electrical connectors. Alternatively, or in addition to an AC bus resident in the container 140, a DC bus may be pre-wired for electrical connection to any one, any combination, or all of: the plurality of battery modules 124; the DC input to the PCS 144; or one or more electrical connectors. As one example, the DC output of the plurality of battery modules 124 may be wired directly to the DC input of the PCS 144. Alternatively, or additionally, conductive wires of the electrical transmission system may be pre-wired such that the plurality of battery modules are connected to the electrical transmission system when the plurality of battery modules are placed on the mechanical structure (e.g., when each battery module is inserted into each slot of the mechanical structure). For example, the mechanical structure may include conductive connectors each for electrical connection to each battery module when the battery modules are placed on the mechanical structure, and pre-wiring for purposes of power transfer includes electrically connecting the conductive wires of the electrical transmission system to the conductive connector of the mechanical structure such that the plurality of battery modules may be electrically connected to the electrical transmission system when the plurality of battery modules are placed on the mechanical structure.

Alternatively, or in addition to configuring an AC bus and/or a DC bus, pre-wiring may be used to supply power to one or more electronic devices (e.g., electronic devices resident within the container 140) and/or route power.

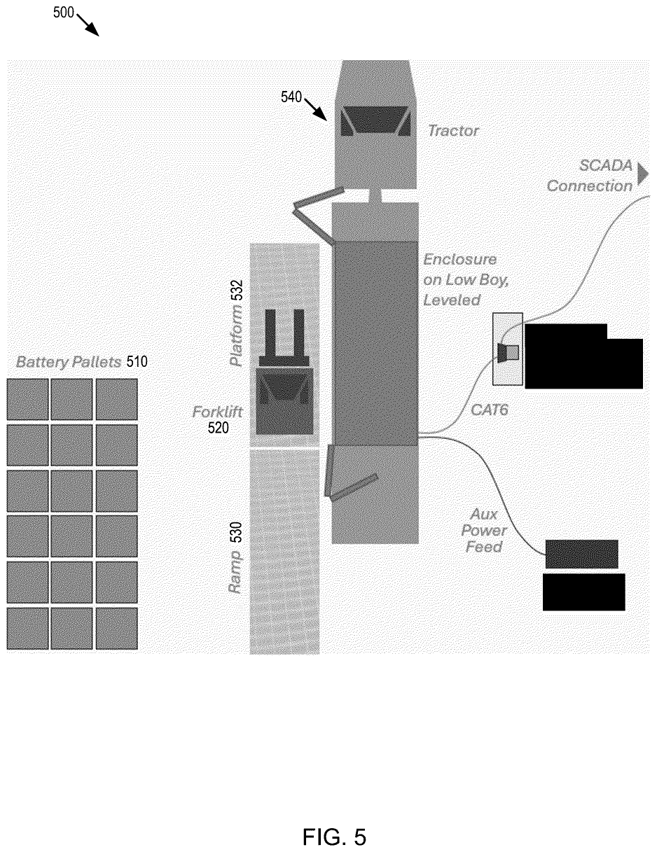

As one example, wires to electrically connect the UPS 138 resident in the container 140 may be electrically pre-wired to one or more electrical devices within or on the container 140, such as any one, any combination, or all of the communication electronics 126, the power electronics 128 (e.g., PCS 144 resident in the container 140), the sensor(s) 130, the climate control system 132, the fire suppression system 134, or the control electronics 136. In one particular example, during the field factory processes, the UPS 138 may be: (i) electrically connected to one or more auxiliary loads; and (ii) at least partly (or entirely) recharged by a separate auxiliary power feed (e.g., by a generator resident at the field factory or by a power feed from the utility grid, see FIG. 5). However, in one or some embodiments, at the field factory, the UPS 138 would not be directly electrically connected to the PCS. Instead, at the field factory, the UPS 138 may be temporarily electrically connected to the separate auxiliary power feed for recharging. At the energy storage site, the UPS 138 may be electrically connected to the PCS (such as PCS 152), such as via a transformer in order align voltages. In this way, one or more preparatory actions may be performed at the field factory in advance of the final installation at the energy storage site.

In another example, pre-configuration for purposes of communication may comprise pre-wiring at the field factory enabling connection of the electronic devices within or on the container 140 to the control electronics 136 separate from the pre-assembled BESS subsystem at the final site later so that the control electronics 136 may communicate with one or more electronic devices within or on the container 140 (e.g., receive data input from electronic devices resident in or on the container 140 and/or send commands for controlling electronic devices resident in or on the container 140) when the pre-wired wires are connected to the control electronics 136 at the final site (e.g., the energy storage site). In yet another example, pre-configuration for purposes of communication may comprise wireless pre-configuration for electronic devices within or on the container 140 such that the control electronics 136 may communicate with one or more electronic devices within or on the container 140. In the case of wireless communication, the pre-configuration for purposes of communication may include wireless communicational connection of the one or more electronic devices within or on the container 140 to the control electronics 136 at the field factory. As discussed above, the pre-configuration may comprise pre-wiring. Alternatively, or in addition, the pre-configuration may comprise installing wireless communication between the different electronic devices so that upon powering the receivers/transmitters at the site, wireless communication may be performed without any additional configuration at the deployment site.

Further, pre-wiring for purposes of grounding may comprise electrically connecting the electronic devices within or on the container 140 (e.g., the plurality of battery modules 124, power electronics 128, sensors 130, climate control system 132, fire suppression system 134, control electronics 136, and/or UPS 138) to the chassis of the container 140. At least a portion of the chassis may be exposed to the exterior of the container 140. At the energy storage site, a user (e.g., a constructor) and/or a machine may electrically connect a metal connector to the exposed portion of the chassis, and the metal connector may be electrically wired to the metal stake or the re-bar on the pad 148, which is driven into earth ground. In this way, for purposes of grounding the electronics, the user or the machine need only electrically connect the metal connector to the chassis at the final energy storage site.

Alternatively, or in addition, mechanical pre-configuration may comprise any one, any combination, or all of the following: assembling, deploying, installing, and/or co-locating components of the pre-assembled BESS subsystem 120 for operation within or on the container 140 for the pre-assembled BESS subsystem 120 (e.g., assembling, deploying, installing, and/or co-locating any one, any combination, or all of: the mechanical structure 122, the plurality battery modules 124, communication electronics 126, power electronics 128, the sensor(s) 130, the climate control system 132, the fire suppression system 134, the control electronics 136, or the UPS 138 within or on the container 140). As one example, any one, any combination, or all of the plurality of battery modules 124, communication electronics 126, power electronics 128, sensors 130, climate control system 132, fire suppression system 134, the control electronics 136, or the UPS 138 may be positioned within the container 140 and mechanically supported by a mechanical structure 122 such as a rack for use at the energy storage site.

When the pre-assembled BESS subsystem 120 includes the control electronics 136 and/or the UPS 138 enclosed within the container 140, the mechanical pre-configuration for the pre-assembled BESS subsystem 120 may include assembling, deploying, installing, configuring, and/or co-latching the control electronics 136 and/or the UPS 138 within the container 140 for the pre-assembled BESS subsystem 120.

When the BESS site configuration 100 includes the control system 110 that is separate from the pre-assembled BESS subsystem 120, the control system 110 may be pre-configured (e.g., pre-assembled) at the field factory and then transported to the energy storage site. In this example, the pre-configuration of the control system 110 may be a separate operation from the pre-configuration of the pre-assembled BESS subsystem 120. For example, pre-configuration of the control system 110 at the field factory may include any one, any combination, or all of: assembling, deploying, installing, configuring, and/or co-latching control electronics 112 within a container for the control system that is different/separate from the container 140 for the pre-assembled BESS subsystem 120; assembling, deploying, installing, configuring, and/or co-latching the UPS 138 within the container for the control system 110; electrically connecting the UPS 138 to the control electronics 136.

In some embodiments, any one, any combination, or all of the following steps associated with installation of the BESS are performed: receiving some or all constitute parts of BESS; configuring one or more pre-assembled BESS subsystem at the field factory; installing one or more pads at the energy storage site; transferring the one or more preassembled BESS subsystem to the energy storage site; installing the pre-assembled BESS subsystem(s) on the pad(s); or connecting the pre-assembled BESS subsystem to one or more components that are separate from the pre-assembled BESS subsystems at the energy storage site.

In some embodiments, configuring one or more pre-assembled BES subsystem at the field factory may include configuring any one, any combination, or all of the components within or on (e.g., attached to) the container for the pre-assembled BESS subsystem at the field factory.

In some embodiments, any one, any combination, or all of the following steps associated with installation of the BESS are performed at the field factory: (i) receiving constitute parts for the pre-assembled BESS subsystem, including a container for the preassembled BESS subsystem, a plurality of battery modules, and/or the like; configuring one or more pre-assembled BESS subsystems by (ii) placing the plurality of battery modules on a mechanical structure configured to support the plurality of battery modules and disposed within the container for the pre-assembled BESS subsystem, (iii) electrically connecting each of the plurality of battery modules to an electrical transmission system configured to transfer electrical energy, (iv) electrically connecting, using the electrical transmission system, the plurality of battery modules to at least one PCS, (v) configuring one or more sensors, (vi) configuring a fire suppression system, (vii) configuring at least a portion of a climate control system (e.g., a local part of the climate control system or the entirety of the climate control system), (viii) installing a power source (e.g., UPS) within the container for the pre-assembled BESS subsystem and independently operated from the plurality of battery modules (also referred to as an independent power source), and wiring for the independent power source, (ix) electrically connecting the independent power source to one or more electronic devices (e.g., control electronics) within or on the container for the pre-assembled BESS subsystem, or (x) communicatively connecting, using communication electronics, the plurality of battery modules and/or electronic components (e.g., sensors, a climate control system, and/or fire suppression system) within or on the container for the pre-assembled BESS subsystem to control electronics within the container for the pre-assembled BESS subsystem.

In some embodiments, one or more constitute parts for the pre-assembled BESS subsystem may be pre-configured within or on the container for the pre-assembled BESS subsystem even before being delivered to the field factory. When one or more constitute parts for the pre-assembled BESS are pre-configured within or on the container for the pre-assembled BESS subsystem before the delivery to the field factory, one or more of steps (i)-(x) may not be performed.

As one example, the mechanical structure to support the plurality of battery modules may be pre-configured (e.g., pre-assembled and pre-installed) within the container for the preassembled BESS subsystem before the container and the mechanical structure are delivered to the field factory. In other words, the method of installing the BESS may include receiving, at the field factory, the container for the pre-assembled BESS subsystem with the mechanical structure installed therein.

Further, as one example, the electrical transmission system may be pre-configured within the container for the pre-assembled BESS subsystem before the container and the electrical transmission system are delivered to the field factory. In other words, the electrical transmission system such as a DC bus, an AC bus, conductive wires connected to the DC bus or AC bus may be pre-installed and/or pre-wired within the container before being delivered to the field factory. In some embodiments, the conductive wires may be pre-wired such that the plurality of battery modules is connected to the electrical transmission system when the plurality of battery modules is placed on the mechanical structure (e.g., when each battery module is inserted into each slot of the mechanical structure) even before the delivery to the field factory.

In some embodiments, one or more PCSs may be pre-configured within the container for the pre-assembled BESS subsystem before the container and the PCS(s) are delivered to the field factory. In some embodiments, both the electrical transmission system and the PCS(s) may be pre-configured within the container such that the electrical transmission system may be electrically connected to the one or more PCSs before the delivery to the field factory such that the plurality of battery modules is connected to the PCSs via the electrical transmission system when the plurality of battery modules is placed on the mechanical structure (e.g., when each battery module is inserted into each slot of the mechanical structure) even before the delivery to the field factory.

In some embodiments, one or more sensors may be pre-configured within the container for the pre-assembled BESS subsystem before the delivery to the field factory. The one or more sensors may be attached to or latched to predetermined positions within the container for the pre-assembled BESS subsystem before the delivery to the field factory such that the sensors may be delivered as being installed on the container for the pre-assembled BESS subsystem when the container for the pre-assembled BESS subsystem is delivered to the field factory.

In some embodiments, at least a portion of the climate control system may be pre-installed within or on the container for the pre-assembled BESS subsystem before the delivery to the field factory. The climate control system may include a local part that is attached to or installed on the container for the pre-assembled BESS subsystem and a remote part that is separate from the pre-assembled BESS subsystem but may be connected to the container for the pre-assembled BESS subsystem or the local part of the climate control system. The local part of the climate control system may also be pre-installed within or on the container for the pre-assembled BESS subsystem before the delivery to the field factory.

In some embodiments, one of more parts of the fire suppression system may be pre-installed within the container for the pre-assembled BESS subsystem before the delivery to the field factory. For example, all components of the fire suppression system except for a tank for holding fire extinguishing agent may be pre-configured within the container for the preassembled BESS subsystem before the delivery to the field factory. When the container for the pre-assembled BESS subsystem is delivered to the field factory, the pre-configured parts of the fire suppression system may be delivered together with the container as being installed in the container.

In some embodiments, some or all parts of the control electronics may be resident within the container for the pre-assembled BESS subsystem, and the parts of the control electronics resident within the container for the pre-assembled BESS subsystem may be pre-configured within the container before the delivery to the field factory. Further, in some embodiments, one or more components of the pre-assembled BESS subsystem controlled by the control electronics may also be pre-installed within or on the container for the preassembled BESS subsystem and communicatively connected to the control electronics before the delivery to the field factory.

In some embodiments, the independent power source (e.g., UPS) resident within the container for the pre-assembled BESS subsystem may be pre-configured within the container for the pre-assembled BESS subsystem before the delivery to the field factory. Further, the wires for the independent power source may also be pre-wired within the container for the pre-assembled BESS subsystem before the delivery to the field factory.

Further, in some embodiments, both the control electronics and the independent power source may be pre-configured within the container for the pre-assembled BESS subsystem before the delivery to the field factory. In this example, the power source may be electrically connected to the control electronics by pre-wiring the wires connecting the power source to the control electronics before the delivery to the field factory. When one or more other electronic components that use the power supplied by the independent power source are pre-configured within the pre-assembled BESS subsystem before the delivery to the field factory, the independent power source may also be electrically connected to these electronic components before the delivery to the field factory.

When the field factory receives components for the BESS, the field factory may perform an acceptance test to verify the received components are functioning properly after the shipment from manufacturing factories to the field factory. Further, when one or more components of the BESS subsystem are pre-configured within or on the container before the delivery to the field factory, the acceptance test performed at the field factory may include verifying that pre-configured components are connected and wired properly. For example, the acceptance test may include a visual check for the components, providing power to the components to test the functionality of the components, and/or measuring both ends of a wire to ensure that the wire is not ripped or split during shipping.

After performing each of one or more of steps (ii)-(x), testing to confirm each step is perform properly may be performed. For example, electrical and/or communicational connections between two or more components may be tested after connecting the components. Further, after installing or configuring one or more components, functionality testing to confirm whether the installed or configured components function properly after the installation may be performed. For example, stability testing to confirm whether the battery modules are properly secured and supported by the mechanical structure after step (ii), electrically testing one or more electrical connections of the plurality of battery modules to the electrical transmission system after step (iii), electrically testing one or more electrical connections of the plurality of battery modules to the at least one PCS after step (iv), testing a functionality of the one or more sensors after step (v), testing a functionality of the fire suppression system after step (vi), testing a functionality of the climate control system or testing a functionality of at least a local part of the climate control system after step (vii), electrically testing the independent power source (e.g., the UPS) or one or more connection of the independent power source (e.g., the UPS) to one or more electronic devices (e.g., the control devices) after steps (viii) and (ix), or communicatively testing one or more communicational connections of the plurality of battery modules and/or the electronic components within or on the container for the pre-assembled BESS subsystem to the control electronics after step (x).

After performing one or more of steps (i)-(x) and additionally or alternatively testing electrical connections, communicational connections, and/or functionalities, the pre-assembled BESS subsystem may be transported from the field factory to the energy storage site. Before transporting the preassembled BESS subsystem, one or more pads (e.g., concrete pads) to support the one or more preassembled BESS subsystem may be constructed at the energy storage site. The one or more preassembled BESS subsystem transported from the field factory to the energy storage site may be installed on the one or more pads at the energy storage site. By way of example, the assembled BESS subsystem may be loaded onto a truck (e.g., a crane, integrated with the truck, may load the assembled BESS subsystem onto the bed of the truck). After which, the truck may be driven to the one or more pads for unloading of the assembled BESS subsystem (e.g., the crane may unload the assembled BESS subsystem onto the pad(s)).

Further, after transporting the pre-assembled BESS subsystem from the field factory to the energy storage site, the pre-assembled BESS subsystem may be connected to one or more components of the BESS that are separate from the pre-assembled BESS subsystem.

In some embodiments, any one, any combination, or all of the following steps associated with installation of a BESS are performed at the energy storage site after transferring the pre-assembled BESS subsystem from the field factory: (a) electrically connecting, via the electrical transmission system, the plurality of battery modules to at least one PCS wherein the at least one PCS is a separate element from the pre-assembled BESS subsystem, (b) communicatively connecting the one or more pre-assembled BESS subsystems to control electronics, (e.g., communicatively connecting, using communication electronics, the plurality of battery modules and/or electronic components (e.g., sensors, a climate control system, and/or fire suppression system) within or on the container for the pre-assembled BESS subsystems to control electronics wherein the control electronics are separate elements from the preassembled BESS subsystem, (c) electrically connect the independent power source (e.g., UPS) to the one or more electronic devices (e.g., control electronics) wherein the independent power source is a separate element from the pre-assembled BESS subsystem, (d) functionally connecting at least a portion of the climate control system (e.g., remote part of the climate control system or the entirety of the climate control system) to each of the one or more preassembled BESS subsystems wherein the at least the portion of the climate control system functionally connected to the one or more pre-assembled EBSS subsystems are separate elements from the pre-assembled BESS subsystem, (e) configuring at least a portion of the fire suppression system (e.g., installing a tank to hold fire extinguishing agent within the container for the BESS subsystem), or (f) grounding the pre-assembled BESS subsystem.

In some embodiments, the PCS(s) may be separated from the pre-assembled BESS subsystem and placed outside the container for the pre-assembled BESS subsystem. In this case, step (iv) may not be performed at the field factory, and step (a) may be performed at the energy storage site. In some embodiments, when BESS includes one or more PCSs included in the pre-assembled BESS subsystem and located within the container for the pre-assembled BESS subsystem and one or more PCSs separate from the pre-assembled BESS subsystem, both step (iv) at the field factory and step (a) at the energy storage site may be performed. In some embodiments, after performing step (a) at the energy storage site, electrically testing one or more electrical connections of the plurality of battery modules to the at least one PCS may be performed at the energy storage site.

Further, in some embodiments, the control electronics may be separated from the pre-assembled BESS subsystem and placed outside the container for the pre-assembled BESS subsystem. In this case, step (x) may not be performed at the field factory, and step (b) may be performed at the energy storage site. In some embodiments, when the BESS includes control electronics included in the pre-assembled BESS subsystem and located within the container for the pre-assembled BESS subsystem and control electronics separate from the pre-assembled BESS subsystem, both step (x) at the field factory and step (b) at the energy storage site may be performed. In some embodiments, even when the BESS includes control electronics separate from the pre-assembled BESS subsystem and located outside the container for the preassembled BESS subsystem, the plurality of battery modules and/or the electronic components may be communicatively connected to the control electronics at the field factory if they are connected via wireless communication. In this case, the wireless connection of the plurality of battery modules and/or the electronic components to the control electronics may be disconnected after the initial connection (e.g., while transferring the pre-assembled BESS subsystem to the energy storage site), but the plurality of battery modules and/or the electronic components to the control electronics may be re-connected at the energy storage site. In some embodiments, after performing step (b), communicatively testing one or more communicational connections of the plurality of battery modules and/or the electronic components within or on the container for the pre-assembled BESS subsystem to the control electronics may be performed at the energy storage site.

In some embodiments, the independent power source (e.g., UPS) may be separated from the pre-assembled BESS subsystem and placed outside the container for the preassembled BESS subsystem. In this case, steps (viii) and (ix) may not be performed at the field factory, and step (c) may be performed at the energy storage site. In some embodiments, when BESS includes both an independent power source located within the container for the preassembled BESS subsystem and an independent power source separate from the pre-assembled BESS subsystem, both steps (viii) and (ix) at the field factory and step (c) at the energy storage site may be performed. In some embodiments, after performing step (c), electrically testing one or more connection of the independent power source (e.g., the UPS) to one or more electronic devices (e.g., the control devices) may be performed at the energy storage site.

In some embodiments, the climate control system may be separated from the preassembled BESS subsystem and placed outside the container for the pre-assembled BESS subsystem. In this case, step (vii) may not be performed at the field factory, and step (d) may be performed at the energy storage site. In some embodiments, when the climate control system includes a local part that is attached to or installed on the container for the pre-assembled BESS subsystem and a remote part that is separate from the pre-assembled BESS subsystem and but may be connected to the pre-assembled BESS subsystem or the local part, both steps (vii) for the local part at the field factory and step (d) for the remote part at the energy storage site may be performed. When at least a portion of the climate control system is functionally connected to each of the one or more pre-assembled BESS subsystems at the energy storage site, the control electronics may be connected to the climate control system also at the energy storage site. In some embodiments, after performing step (d), testing a functionality of the climate control system may be performed at the energy storage site.

In some embodiments, at least a portion of the fire suppression system may be configured at the energy storage site (step (e)). For example, the tank for holding the fire extinguishing agent of the fire suppression system may be installed at the energy storage site. Installing the tank for holding the fire extinguishing agent at the energy storage site may minimize or reduce the risk of maloperation of the fire suppression system caused by uncontrolled vibrations or impact while transferring the pre-assembled BESS subsystem to the energy storage site. In some embodiments, after performing step (e), testing a functionality of the fire suppression system may be performed at the energy storage site.

For grounding (step (f)), after transporting the pre-assembled BESS subsystem from the field factory to the energy storage site, an exposed portion of the chassis of the container for the pre-assembled BESS subsystem may be connected to the metal stake or the re-bar on the pad at the energy storage site. The chassis of the container for the pre-assembled BESS subsystem may be connected to the metal stake or the re-bar via the metal connector.

In one or some embodiments, the field factory may be configured as an assembly line that is composed of one or more stations. For example, one or more stations may perform the functions and the steps described above, such as any one, any combination, or all of: (ii); (iii); (iv); (v); (vi); (vii); (viii); (ix); or (x). In this regard, the field factory may comprise a makeshift assembly line in which the various functions and steps described above may be performed at different stations therein.

As shown above, one of the differences between the disclosed process and other processes to configure a BESS includes that a part of the construction process of the BESS is performed at the field factory and another part of the process of the construction process is performed at the energy storage site.

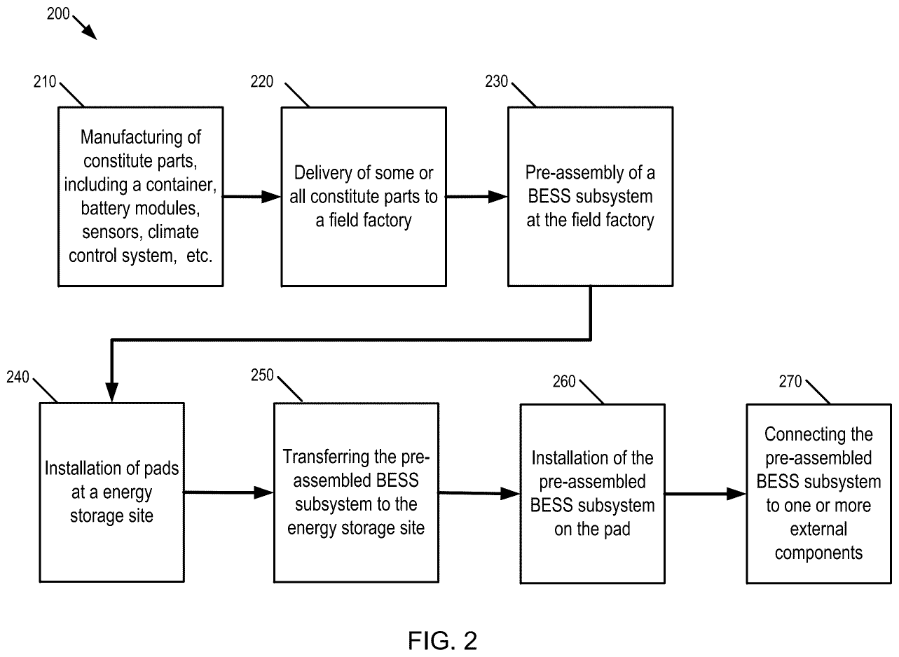

FIG. 2 is a flow diagram 200 illustrating an example process of using a field factory to construct a BESS. Referring to FIG. 2, as discussed above, a field factory may be used as part of the overall process of constructing the BESS. At 210, the manufacturing of the constituent parts of the BESS may be performed. As one example, one or more manufacturing factories may manufacture a container for the pre-assembled BESS subsystem, a mechanical structure, battery modules, sensors, a climate control system, and/or the like. As another example, manufacturing factories may assemble one or more constituent parts (e.g., a mechanical structure, sensors, etc.) within or on the container for the pre-assembled BESS subsystem. In turn, at 220, the constituent parts may be delivered (either directly or via in intermediary) to a field factory. When the one or more constituent parts are pre-assembled within or on the container for the pre-assembled BESS subsystem at the factory, the pre-assembled constituent parts are shipped to the field factory together with the container for the pre-assembled BESS subsystem as being assembled. At 230, the field factory may assemble the pre-assembled BESS subsystem (e.g., performing any one, any combination, or all of: placing the plurality of battery modules on a mechanical structure configured to support the plurality of battery modules and disposed within the container for the pre-assembled BESS subsystem; electrically connecting each of the plurality of battery modules to an electrical transmission system configured to transfer electrical energy; electrically connecting, using the electrical transmission system, the plurality of battery modules to at least one PCS; configuring one or more sensors; configuring a fire suppression system; configuring at least a portion of a climate control system (e.g., a local part of the climate control system or the entirety of the climate control system); installing a power source (e.g., UPS) within the container for the pre-assembled BESS subsystem and independently operated from the plurality of battery modules (also referred to as an independent power source), and wiring for the independent power source; electrically connecting the independent power source to one or more electronic devices (e.g., control electronics) within or on the container for the pre-assembled BESS subsystem; or communicatively connecting, using communication electronics, the plurality of battery modules and/or electronic components (e.g., sensors, a climate control system, and/or fire suppression system) within or on the container for the pre-assembled BESS subsystem to control electronics within the container for the pre-assembled BESS subsystem).

In one embodiment, the field factory is on-site (e.g., proximate to or at the energy storage site). Alternatively, the field factory is remote or off-site from the energy storage site such that the pre-assembled BESS subsystems are transported by a truck or the like from the field factory to the energy storage site, which is less than 1 mile away from the field factory, less than 5 miles away from the field factory, or less than 10 miles away from the field factory.

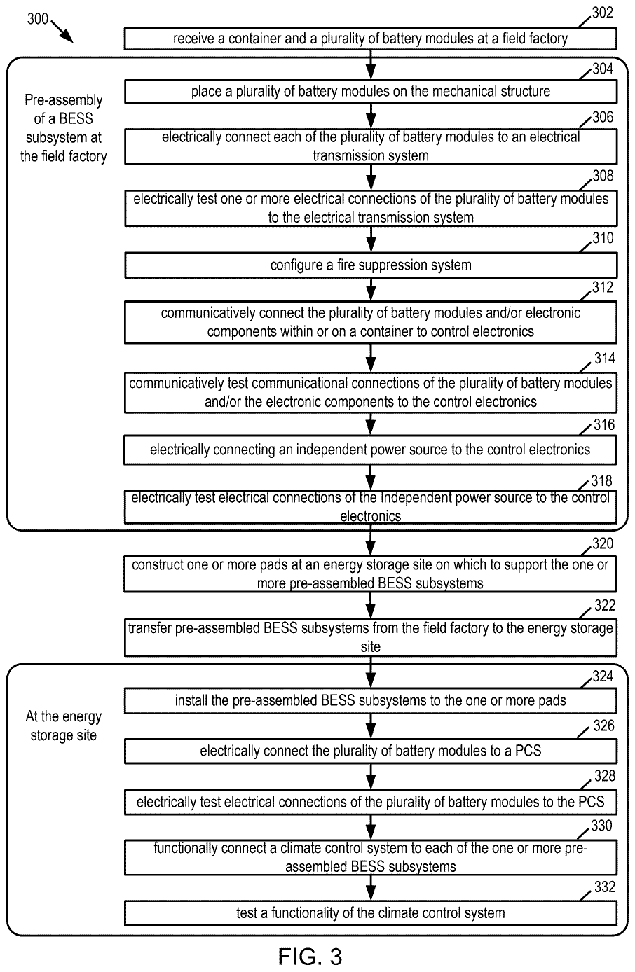

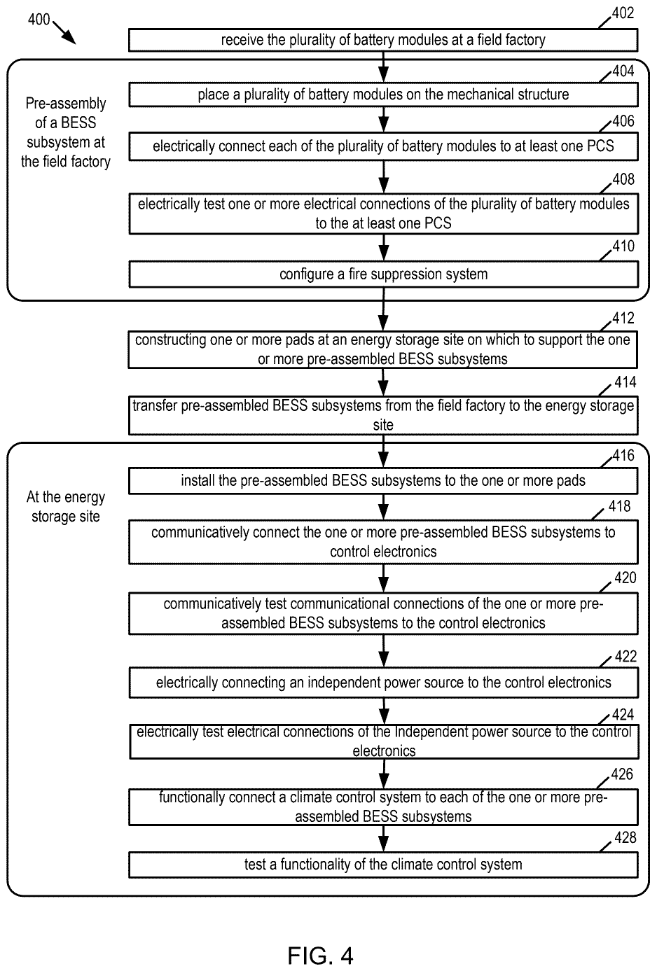

At 240, one or more pads to support the pre-assembled BESS subsystems are installed at the energy storage site. Then, at 250, the pre-assembled BESS subsystem is transferred from the filed factory to the energy storage site. When the field factory is on-site, the pre-assembled BESS subsystem may be transferred by a crane or the like. When the field factory is remote or off-site from the energy storage site, the pre-assembled BESS subsystem may be transferred by a truck or the like. At 260, each of the one or more pre-assembled BESS subsystem is installed on each of the one or more pads. Installation of the pre-assembled BESS subsystems on the pads may include placing each pre-assembled BESS subsystem to the pre-determined position on each pad. Then, at 270, when there are any external components that should be connected to the pre-assembled BESS subsystem for operation of the BESS and are separate or distinguished from the pre-assembled BESS subsystem, these external components may be connected to the pre-assembled BESS subsystem (for one instance, connected to one or more constituent parts of the pre-assembled BESS subsystem) at the energy storage site. Further details of the overall construction process are discussed below with regard to FIGS. 3 and 4.

FIG. 3 is a flow diagram 300 illustrating another example process of using a field factory to construct a BESS wherein the PCS is separated from the pre-assembled BESS subsystem and located outside a container for the pre-assembled BESS subsystem, and the control electronics and an independent power source (e.g., UPS) are located within the container for the pre-assembled BESS subsystem. At 302, the field factory may receive constituent parts, including a plurality of battery modules and a container for the pre-assembled BESS subsystem. In some embodiments, a mechanical structure configured to support the plurality of battery modules may be pre-assembled and pre-installed within the container for the pre-assembled BESS subsystem. In this case, the field factory may receive the container for the pre-assembled BESS subsystem together with the mechanical structure. As discussed above, the field factory may perform the assembly of the pre-assembled BESS subsystem. For example, the field factory may perform 304-318. At 304, the plurality of battery modules is placed on a mechanical structure disposed within a container for the pre-assembled BESS subsystem. At 306, each of the plurality of battery modules is electrically connected to an electrical transmission system configured to transfer electrical energy. Electrically connecting the each of the plurality of battery modules to the electrical transmission system may include electrically connecting the plurality of battery modules to a power bus of the electrical transmission system.

At 308, one or more electrical connections of the plurality of battery modules to the electrical transmission system are electrically tested. Electrical testing of the one or more electrical connections of the plurality of battery modules to the electrical transmission system includes electrically testing a plurality of connections of the plurality of battery modules to the power bus. At 310, a fire suppression system may be configured within the container for the pre-assembled BESS subsystem. At 312, the plurality of battery modules and electronic components within or on the container for the pre-assembled BESS subsystems are connected to control electronics within the container for the pre-assembled BESS subsystem. At 314, one or more communicational connections of the plurality of battery modules and the electronic components to the control electronics are communicatively tested. At 316, a power source independently operated from the polarity of battery modules (i.e., independent power source, e.g., UPS) may be electrically connected to the control electronics. In some embodiments, the field factory may receive the power source as being pre-installed and pre-wired within the container for the pre-assembled BESS subsystem before being received at the field factory. In some embodiments, in addition to the independent power source, the control electronics may be pre-installed within the container for the pre-assembled BESS subsystem before being received at the field factory and, further, the power source is electrically connected to the control electronics before being received at the field factory. In this example, 316 may not be performed at the field factory. At 318, one or more electronical connections of the power source to the control electronics may be tested at the field factory.

In some embodiments, the field factory may also perform receiving a climate control system or at least a portion of the climate control system pre-installed and/or pre-wired within or on the container for the pre-assembled BESS subsystem before being received at the field factory. In this example, the climate control system may be received at the field factory when the container for the pre-assembled BESS subsystem is received at the field factory at 302.

In some embodiments, the field factory may also perform receiving one or more sensors pre-installed and/or pre-wired within or on a container for the pre-assembled BESS subsystem before being received at the field factory. In this example, the one or more sensors may be received at the field factory when the container for the pre-assembled BESS subsystem is received at the field factory at 302.

At 320, one or more pads on which to support the one or more pre-assembled BESS subsystems are constructed at the energy storage site. Construction of the one or more pads may include configuring a re-bar or a metal stake for grounding on each of the one or more pads. At 322, one or more pre-assembled BESS subsystems are transferred from the field factory to the energy storage site. At 324, the one or more pre-assembled BESS subsystems are installed on the one or more pads. At 326, the plurality of battery modules is electrically connected to at least one PCS via the electrical transmission system. At 328, one or more electrical connections of the plurality of battery modules to the at least one PCS are electrically tested.

When at least a portion of the climate control system (i.e., a remote part-for example, a control part of the climate control system, a motor of the climate control system, or the like; or the entirety of the climate control system) is located outside the container for the pre-assembled BESS subsystem and separated from the pre-assembled BESS subsystem, at the energy storage site, the at least the portion of the climate control system is functionally connected to each of the one or more pre-assembled BESS subsystem or the local part of the climate control system that has been installed on the container for the pre-assembled BESS subsystem at 330. At 332, the functionality of the climate control system is tested at the energy storage site.

FIG. 4 is a flow diagram 400 illustrating another example process of using a field factory to construct a BESS wherein the PCS is located within a container for the pre-assembled BESS subsystem, and the control electronics and an independent power source (e.g., UPS) are separated from the pre-assembled BESS subsystem and located outside the container for the pre-assembled BESS subsystem. At 402, the field factory may receive constituent parts, including a plurality of battery modules and a container for the pre-assembled BESS subsystem. The field factory may perform 404-410 to assemble the BESS subsystem. At 404, the plurality of battery modules is placed on a mechanical structure disposed within a container for the pre-assembled BESS subsystem. At 306, each of the plurality of battery modules is electrically connected to at least one PCS. The plurality of battery modules may be electrically connected to the at least one PCS via an electrical transmission system configured to transfer electrical energy. Electrically connecting the each of the plurality of battery modules to the at least one PCS may include electrically connecting the plurality of battery modules to a power bus of the electrical transmission system, and electrically connecting the power bus to the at least one PCS. At 408, one or more electrical connections of the plurality of battery modules to at least one PCS are electrically tested. Electrical testing of the one or more electrical connections of the plurality of battery modules to the at least one PCS may include electrically testing a plurality of connections of the plurality of battery modules to the power bus and electrically testing the connection of the power bus to the at least one PCS. At 410, a fire suppression system may be configured within the container for the pre-assembled BESS subsystem.

At 412, one or more pads on which to support the one or more pre-assembled BESS subsystems are constructed at the energy storage site. At 414, one or more pre-assembled BESS subsystems are transferred from the field factory to the energy storage site. At 416, the one or more pre-assembled BESS subsystems are installed on the one or more pads.

At 418, one or more pre-assembled BES subsystems are communicatively connected to the control electronics at the energy storage site. For one instance, each of one or more components of the pre-assembled BESS subsystem controlled by the control electronics may be communicatively connected to the control electronics at the energy storage site. For another instance, a communication panel or a communication hub of the pre-assembled BESS subsystem that forwards the control signals from the control electronics to each component of the pre-assembled BESS subsystem controlled by the control electronics may be communicatively connected to the control electronics at the energy storage site. In some embodiments, each component of the pre-assembled BESS subsystem controlled by the control electronics may be communicatively connected to the communication panel or the communication hub at the field factory before being transferred to the energy storage site. At 420, one or more communicational connections of the one or more pre-assembled BESS subsystems to the control electronics may be communicatively tested at the energy storage site.

At 422, an independent power source (e.g., UPS) may be electrically connected to the control electronics. The independent power source may also be electrically connected to one or more electronic components of the pre-assembled BESS subsystem that need to be connected to the independent power source at the energy storage site. Then, at 424, one or more connections of the independent power source to the control electronics and/or the one or more electronic components of the pre-assembled BESS subsystem are electrically tested at the energy storage site.

At 426, the climate control system (e.g., at least the portion of the climate control system-remote part of the climate control system; or the entirety of the climate control system) is functionally connected to each of the one or more pre-assembled BESS subsystem or the local part of the climate control system that has been pre-installed on the container for the preassembled BESS subsystem at the field factory or before delivery to the filed factory. At 428, the functionality of the climate control system is tested at the energy storage site.

FIG. 5 is a top view of an illustration 500 of the field factory. As discussed above, the field factory may configure the pre-assembled BESS subsystems 120. In one or some embodiments, the field factory may include an enclosure (e.g., a temporary enclosure such as a tent). Various constituent parts of the pre-assembled BESS subsystems 120 may be moved into the enclosure. As one example, battery pallets 510 may be moved into the enclosure. As discussed above, the battery pallets 510 (a plurality of which are illustrated in FIG. 5) may be housed within a container, with the container being repurposed as the container for the preassembled BESS subsystems 120. Alternatively, batteries within the battery pallets 510 may be removed and inserted into separate containers. In practice, a truck 540 may be driven into the enclosure of the field factory and positioned proximate to a platform 532 (e.g., a 20-foot platform). A forklift 520 may pick up various parts, such as the batteries and/or the battery pallets 510, and drive up the ramp 530 (e.g., a 20-foot ramp) onto the platform 532 in order to unload the various parts onto the truck 540 (e.g., the enclosure on lowboy or low-loader on the truck). As such, the configuration and/or testing of the various parts of the pre-assembled BESS subsystems 120 may be performed on the truck. For example, the field factory may use power, such as from an electrical grid (routed via a SCADA connection) and/or from an alternate power source (e.g., a generator 550 or other auxiliary power source) (routed via an auxiliary power feed). Merely by way of one example, power, whether from the electrical grid or an auxiliary source, may be used in the configuration and/or testing of the pre-assembled BESS subsystems 120, such as UPS 138. Further by way of another example, the field factory may include a commissioning station 560 that uses power in performing the commissioning process, which may comprise a systematic approach to ensure that the pre-assembled BESS subsystems 120 are configured and tested properly.

After completion of the configuration and/or testing of the various parts of the preassembled BESS subsystems 120, the truck 540 (with the pre-assembled BESS subsystem(s) 120 already loaded thereon) may be driven to the energy storage site whereupon the preassembled BESS subsystems 120 may be loaded onto the foundation (e.g., a crane 542 or other lifting machinery may move the pre-assembled BESS subsystems 120 onto the foundation for final construction and/or testing at the energy storage site).

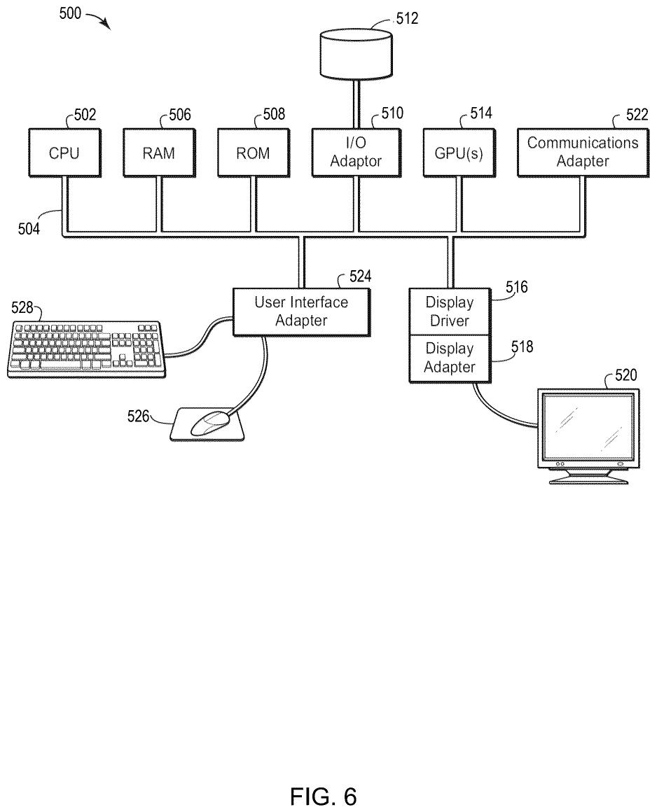

In all practical applications, the present technological advancement may (or must) be used in conjunction with a computer, programmed in accordance with the disclosures herein. Merely by way of example, various devices disclosed in the present application may comprise a computer or may work in combination with a computer (e.g., executed by a computer), such as any one, any combination, or all of the steps disclosed in FIGS. 2-4. In particular, any one, any combination, or all of the operations performed at the field factory may be controlled (such as automatically controlled) by computer(s). Merely by way of example, FIG. 6 is a diagram of an exemplary computer system 600 that may be utilized to implement methods, including the flow diagrams, described herein. A central processing unit (CPU) 602 is coupled to system bus 604. The CPU 602 may be any general-purpose CPU, although other types of architectures of CPU 602 (or other components of exemplary computer system 600) may be used as long as CPU 602 (and other components of computer system 600) supports the operations as described herein. Those of ordinary skill in the art will appreciate that, while only a single CPU 602 is shown in FIG. 6, additional CPUs may be present. Moreover, the computer system 600 may comprise a networked, multi-processor computer system that may include a hybrid parallel CPU/GPU system. The CPU 602 may execute the various logical instructions according to various teachings disclosed herein. For example, the CPU 602 may execute machine-level instructions for performing processing according to the operational flow described herein.

The computer system 600 may also include computer components such as non-transitory, computer-readable media. Examples of computer-readable media include computer-readable non-transitory storage media, such as a random-access memory (RAM) 606, which may be SRAM, DRAM, SDRAM, or the like. The computer system 600 may also include additional non-transitory, computer-readable storage media such as a read-only memory (ROM) 608, which may be PROM, EPROM, EEPROM, or the like. RAM 606 and ROM 608 hold user and system data and programs, as is known in the art. In this regard, computer-readable media may comprise executable instructions to perform any one, any combination, or all of the blocks in the flow charts in FIGS. 2-4. The computer system 600 may also include an input/output (I/O) adapter 610, a graphics processing unit (GPU) 614, a communications adapter 622, a user interface adapter 624, a display driver 616, and a display adapter 618.

The I/O adapter 610 may connect additional non-transitory, computer-readable media such as storage device(s) 612, including, for example, a hard drive, a compact disc (CD) drive, a floppy disk drive, a tape drive, and the like to computer system 600. The storage device(s) may be used when RAM 606 is insufficient for the memory requirements associated with storing data for operations of the present techniques. The data storage of the computer system 600 may be used for storing information and/or other data used or generated as disclosed herein. For example, storage device(s) 612 may be used to store configuration information or additional plug-ins in accordance with the present techniques. Further, user interface adapter 624 couples user input devices, such as a keyboard 628, a pointing device 626 and/or output devices to the computer system 600. The display adapter 618 is driven by the CPU 602 to control the display on a display device 620 to, for example, present information to the user such as images generated according to methods described herein.

The architecture of computer system 600 may be varied as desired. For example, any suitable processor-based device may be used, including without limitation personal computers, laptop computers, computer workstations, and multi-processor servers. Moreover, the present technological advancement may be implemented on application specific integrated circuits (ASICs) or very large scale integrated (VLSI) circuits. In fact, persons of ordinary skill in the art may use any number of suitable hardware structures capable of executing logical operations according to the present technological advancement. The term “processing circuit” encompasses a hardware processor (such as those found in the hardware devices noted above), ASICs, and VLSI circuits. Input data to the computer system 600 may include various plug-ins and library files. Input data may additionally include configuration information.

It is intended that the foregoing detailed description be understood as an illustration of selected forms that the invention may take and not as a definition of the invention. It is only the following claims, including all equivalents which are intended to define the scope of the claimed invention. Further, it should be noted that any aspect of any of the preferred embodiments described herein may be used alone or in combination with one another. Finally, persons skilled in the art will readily recognize that in preferred implementation, some, or all of the steps in the disclosed method are performed using a computer so that the methodology is computer implemented.

What is claimed is:

1. A method of installing a battery energy storage system (BESS) comprising a plurality of battery modules at an energy storage site, the method comprising:
at a field factory:
receiving, at the field factory locationally separate from the energy storage site, the plurality of battery modules;
configuring, at the field factory, one or more pre-assembled BESS subsystems by:
placing the plurality of battery modules on a mechanical structure disposed within a container for the pre-assembled BESS subsystem and configured to support the plurality of battery modules;
electrically connecting each of the plurality of battery modules to an electrical transmission system configured to transfer electrical energy;
electrically testing one or more electrical connections of the plurality of battery modules to the electrical transmission system; and
configuring one or more of a fire suppression system, an internal climate control system, communication electronics, a sensor system, BESS subsystem control electronics, or a BESS subsystem universal power supply;
transferring the one or more pre-assembled BESS subsystems from the field factory to the energy storage site; and
at the energy storage site:
constructing one or more pads at the energy storage site on which to support the one or more pre-assembled BESS subsystems;
installing the one or more pre-assembled BESS subsystems on the one or more pads;
electrically connecting the plurality of battery modules to at least one power conversion system (PCS) via the electrical transmission system; and
electrically testing one or more electrical connections of the plurality of battery modules to the at least one PCS.

2. The method of claim 1, wherein configuring, at the field factory, the one or more preassembled BESS subsystems comprises:
communicatively connecting the plurality of battery modules and electronic components within or on a container for the pre-assembled BESS subsystems to the control electronics; and
communicatively testing one or more communicational connections of the plurality of battery modules and the electronic components within or on the container for the pre-assembled BESS subsystems to the control electronics.

3. The method of claim 2, further comprising receiving, at the field factory, a power source independently operated from the plurality of battery modules; and
wherein the power source is pre-installed and pre-wired within the container for the pre-assembled BESS subsystem before being received to the field factory.

4. The method of claim 3, wherein the power source is electrically connected to the control electronics before being received at the field factory.

5. The method of claim 3, wherein configuring, at the field factory, the one or more preassembled BESS subsystems comprises:
electrically connecting, at the field factory, the power source to the control electronics; and
electrically testing, at the field factory, one or more electrical connections of the power source to the control electronics.

6. The method of claim 1, wherein the one or more pre-assembled BESS subsystems includes the BESS subsystem control electronics for controlling a respective pre-assembled BESS subsystem;
wherein the BESS subsystem control electronics is tested at the field factory;
wherein the BESS includes BESS control electronics for controlling a plurality of preassembled BESS subsystems;
further comprising:
at the energy storage site:
communicatively connecting the plurality of pre-assembled BESS subsystems to the BESS control electronics; and
communicatively testing one or more communicational connections of the plurality of pre-assembled BESS subsystems to the BESS control electronics.

7. The method of claim 6, wherein the one or more pre-assembled BESS subsystems includes the BESS subsystem universal power supply for powering the control electronics for the respective pre-assembled BESS subsystem;
wherein the BESS subsystem universal power supply is tested at the field factory;
wherein the BESS includes a BESS universal power supply for powering the BESS control electronics;
further comprising:
at the energy storage site:
electrically connecting the BESS universal power supply; and
electrically testing one or more connections of the BESS universal power supply to the BESS control electronics.

8. The method of claim 1, further comprising receiving, at the field factory, the internal climate control system; and
wherein the internal climate control system is one or both of pre-installed or pre-wired within or on the container for the pre-assembled BESS subsystem before being received at the field factory.

9. The method of claim 1, wherein the one or more pre-assembled BESS subsystems includes the internal climate control system for controlling climate for a respective preassembled BESS subsystem;
wherein the internal climate control system is tested at the field factory; and
further comprising, at the energy storage site, installing and testing an external climate control system for controlling the climate for the one or more pre-assembled BESS subsystems.

10. The method of claim 1, wherein the one or more pre-assembled BESS subsystems includes at least one power conversion system (PCS) for a respective pre-assembled BESS subsystem;
wherein the PCS is tested at the field factory; and
further comprising, at the energy storage site, installing and testing a separate PCS for the one or more pre-assembled BESS subsystems.

11. The method of claim 1, further comprising:
at the energy storage site:
functionally connecting a climate control system to each of the one or more preassembled BESS subsystems; and
testing a functionality of the climate control system.

12. The method of claim 1, wherein the electrical transmission system includes a power bus;
wherein configuring, at the field factory, the one or more pre-assembled BESS subsystems further comprises electrically connecting the plurality of battery modules to the power bus; and
wherein configuring, at the field factory, the one or more pre-assembled BESS subsystems further comprises electrically testing a plurality of connections of the plurality of battery modules to the power bus.

13. The method of claim 1, further comprising:
receiving, at the field factory, a container for the pre-assembled BESS subsystem with the mechanical structure, wherein the mechanical structure is pre-assembled and pre-installed on the container before being received at the field factory.

14. The method of claim 1, further comprising receiving, at the field factory, one or more sensors; and
wherein the one or more sensors are one or both of pre-assembled or pre-wired within a container for the pre-assembled BESS subsystem before being received at the field factory.

15. A method of installing a battery energy storage system (BESS) comprising a plurality of battery modules at an energy storage site, the method comprising:
at a field factory:
receiving, at the field factory locationally separate from the energy storage site, the plurality of battery modules;
configuring, at the field factory, one or more pre-assembled BESS subsystems by:
electrically connecting the plurality of battery modules to at least one power conversion system (PCS);
electrically testing one or more electrical connections of the plurality of battery modules to the at least one PCS; and
configuring one or more of a fire suppression system, an internal climate control system, communication electronics, a sensor system, BESS subsystem control electronics, or a BESS subsystem universal power supply;
transporting the one or more pre-assembled BESS subsystems from the field factory to the energy storage site; and
at the energy storage site:
constructing one or more pads at the energy storage site on which to support the one or more pre-assembled BESS subsystems;
installing the one or more pre-assembled BESS subsystems to the one or more pads;
communicatively connecting the one or more pre-assembled BESS subsystems to BESS control electronics configured to control the one or more pre-assembled BESS subsystems; and
communicatively testing one or more communicational connections of the one or more pre-assembled BESS subsystems to the BESS control electronics.

16. The method of claim 15, further comprising:
at the energy storage site:
electrically connecting a universal power supply (UPS) to the BESS control electronics; and
electrically testing a connection of the UPS to the BESS control electronics.

17. The method of claim 16, wherein the one or more pre-assembled BESS subsystems includes the BESS subsystem universal power supply for powering the control electronics for a respective pre-assembled BESS subsystem; and
wherein the BESS subsystem universal power supply is tested at the field factory.

18. The method of claim 14, further comprising receiving, at the field factory, the internal climate control system; and
wherein the internal climate control system is one or both of pre-installed or pre-wired within or on a container for the pre-assembled BESS subsystem before being received at the field factory.

19. The method of claim 14, wherein the one or more pre-assembled BESS subsystems includes the internal climate control system for controlling climate for a respective preassembled BESS subsystem;
wherein the internal climate control system is tested at the field factory; and
further comprising, at the energy storage site, installing and testing an external climate control system for controlling the climate for the one or more pre-assembled BESS subsystems.

20. The method of claim 14, wherein electrically connecting the plurality of batteries to at least one PCS includes:
electrically connecting the plurality of batteries to a power bus;
electrically connecting the power bus connected to the plurality of batteries to the at least one PCS;
wherein electrically testing one or more electrical connections of the plurality of battery modules to the at least one PCS includes:
electrically testing a plurality of connections of the plurality of battery modules to the power bus; and
electrically testing a connection of the power bus to at least one PCS.

21. The method of claim 20, further comprising, at the energy storage site, installing and testing at least one external PCS for the one or more pre-assembled BESS subsystems.

22. The method of claim 14, further comprising:
receiving, at the field factory, a container for the pre-assembled BESS subsystem with a mechanical structure, wherein the mechanical structure is pre-assembled and pre-installed within the container before being received at the field factory.

23. The method of claim 14, further comprising receiving, at the field factory, one or more sensors; and
wherein the one or more sensors are one or both of pre-assembled or pre-wired within a container for the pre-assembled BESS subsystem before being received at the field factory.
